(19) United States
(12) Patent Application Publication
(10) Pub. No.: US 2008/0116494 A1
(43) Pub. Date: May 22, 2008

(54) Method for manufacturing a semiconductor device

(76) Inventors: Matthias Goldbach, Dresden (DE); Dietmar Henke, Radebeul (DE); Sven Schmidbauer, Dresden (DE)

Correspondence Address: JENKINS, WILSON, TAYLOR & HUNT, P. A., 3100 TOWER BLVD., Suite 1200, DURHAM, NC, 27707, US

(21) Appl. No.: 11/602,066

(22) Filed: Nov. 20, 2006

(51) Int. Cl. H01L 29/76; H01L 21/265; H01L 21/4763

(52) U.S. Cl. 257/288; 438/518; 438/622; 257/E29.226; 257/E21.495; 257/E21.334

(57) ABSTRACT

The invention relates to a method for manufacturing a semiconductor device. A silicon substrate comprising at least one structured area in which a dopant is implanted is provided. A contact modifying material is provided on the surface of the at least one structured area. A silicide layer is formed on the surface of the at least one structured area, the silicide layer comprising at least one of titan silicide, titan nitride silicide and cobalt silicide.

### BACKGROUND OF THE INVENTION

1. Field of the Invention

The present invention relates to a method for manufacturing a semiconductor device. Further, the present invention relates to a semiconductor device manufactured by the inventive method.

2. Description of the Related Art

Although in principle applicable to arbitrary integrated semiconductor structures, the following invention and the underlying problems will be explained with respect to integrated DRAM memory circuits in silicon technology.

A DRAM memory device comprises a plurality of memory cells in which information is stored in form of electric charges in capacitors. Access to the electric charge is controlled by selection transistors.

There is a major interest in reducing the time needed to store charges, thus information, in the capacitor via the selection transistor. A lower limit to the access time is given by the low pass filter characteristic (RC characteristic) of the selection transistor and the contacts contacting the selection transistor.

It is of interest to reduce the voltage drop in contacts and interfaces. Hence, a low resistivity of interfaces and contacts is demanded.

The selection transistors in memory cells are generally formed as n-FET transistors. Hence, the drain-source regions of the selection transistors are highly n-doped. The source-drain regions are contacted via a metallic plug. At the interface of the metallic plug and the silicon drain region, a metal silicide is formed.

The interface of the highly doped source-drain region and the metal silicide exhibits a Schottky potential barrier due to the different Fermi levels of metal silicide and doped silicon. The Schottky potential barrier contributes to the resistivity of the selection transistor and increases the lower limit of the delay time for access to charges in the capacitor.

### BRIEF SUMMARY OF THE INVENTION

The present invention provides a method for forming a contact region wherein the contact region exhibits a low potential barrier.

The inventive method for manufacturing a semiconductor device, comprises the steps of:
(a) providing a silicon substrate comprising at least one structured area in which a dopant is implanted;
(b) providing a contact modifying material onto the surface of the at least one structured area;
(c) forming a silicide layer on the surface of the at least one structured area, the silicide layer comprising at least one of titan silicide, titan nitride silicide, cobalt silicide, nickel silicide, ytterbium silicide, erbium silicide, platinum silicide, palladium silicide and rhenium silicide.

The device formed by the inventive method comprises:
a source/drain region,
a contact comprising a lower portion made of a metal silicide,
a conductive layer comprising a contact modifying material, an upper side of the layer being adjacent to the metal silicide of the contact and a lower side of the layer being adjacent to the source/drain region.

The contact modifying material reduces the Schottky barrier height. Hence, the resistivity of the contact is reduced and the RC-constant lowered. DRAM devices and logic devices which incorporate such contacts have a potential to improve the access time for data and the voltage drops in the devices.

The concentration of the dopant material may be at least 5 10¹⁸ atoms per cm³.

The structured area may be a source/drain region of a transistor, e.g. a transistor of a logic device, or a contact area for contacting a source/drain region of a memory cell.

Titan silicide, titan nitride silicide, cobalt silicide, ytterbium silicide, and erbium silicide are particular well suited for n-doped structured areas. Platinum silicide, palladium silicide and rhenium silicide are preferably used for p-doped structured areas. Nickel silicide can be mixed to any of the other silicides.

The silicon substrate comprising the dopants may be subjected to a high thermal activation process for activating the dopants. In a next step the contact modifying material is implanted into or deposited on the structured area of the doped silicon substrate. The silicide layer is formed on the modified and doped structured area. This type of formation is of particular interest for the fabrication of semiconductor memory devices, e.g. DRAMs.

The contact modifying material may be first implanted into the structured area and afterwards the dopants are activated by a high temperature step.

The silicide layer is formed on the modified and doped structured area. This type of formation is of particular interest for the fabrication of logic devices.

The silicide layer may be formed first and afterwards the contact modifying material may be implanted through the silicide layer to the surface of the at least one structured area. As there is no need for an activation step of the contact modifying material, the contact modifying material can be applied at a later stage of the method.

The passivation material may be deposited on the surface of the at least one contact area and the silicide layer may be formed on the surface provided with the passivation material

The contact modifying material can be introduced into a reaction chamber during the forming of the silicide layer.

The contact modifying material can comprise sulphur.

The contact modifying material can comprise selenium, lanthanum, strontium, gadolinium, tellurium, rare earth metals, in particular for n-doped structured areas. Aluminium, indium, gallium may be used for p-doped structured areas. Further, germanium, silicon, xenon and argon can be used for implanting a contact modifying material.

The concentration of the contact modifying material preferably exceeds 10¹³ atoms per cm³. A lower concentration shows an undesired increase of the Schottky barrier, e.g. when sulphur is used as contact modifying material for heavily p-doped structured areas, when also implanted into the p-doped structured areas.

The silicon substrate may be provided with prefabricated semiconductor devices contacted via the structured areas, and wherein an isolation layer is provided over the silicon substrate for covering the prefabricated semiconductor devices and openings are formed into the isolation layer. The contact modifying material is provided through the opening and the silicide layer is formed in the opening.

The lower portion of the contact can extend into the source/drain region.

The lower portion of the contact may be planar and may cover a top surface of the source/drain region.

A semiconductor memory comprises one of the above transistors.

### DESCRIPTION OF THE DRAWINGS

Preferred embodiments of the method for manufacturing capacitor structures according to the invention will be described below with reference to the attached figures for explaining the features of the invention.

In the figures:

FIG. 1 to 4 show partial cross-sections of silicon substrate to illustrate a method of forming a contact according to a first embodiment;

FIG. 5 to 8 show partial cross-sections of silicon substrate to illustrate a method of forming a contact according to a second embodiment;

FIG. 9 shows a partial cross-section of a transistor; and

FIG. 10 shows a partial cross-section of a transistor.

### BRIEF DESCRIPTION OF THE PREFERRED EMBODIMENTS

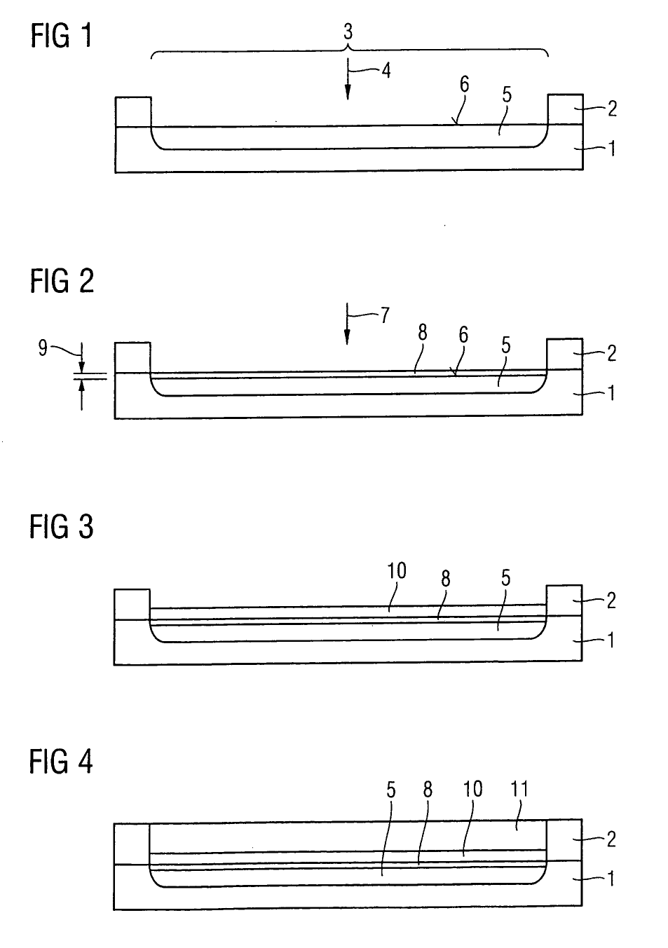

Identical reference signs denote identical or similar elements in the FIGS. 1-10.

The first embodiment of the inventive method for forming a contact is illustrated along with FIGS. 1-4. FIG. 1 shows a partial cross section of a silicon substrate 1. The part of the silicon substrate 1 shown in FIG. 1 can be n-doped, e.g. if this part represents a source-drain region of a MOSFET transistor. A mask 2 is applied on the silicon substrate 1 to define a structured area 3. The structured area can be a contact area on or in a source/drain area or the source/drain area itself.

In a first but optional step, a doped material 4 is deposited in a high dose into the silicon substrate 1. The highly doped area 5, i.e. of concentration of at least 5*10¹⁸ atoms per cm³, extends preferably to the surface 6 of the silicon substrate 1. The polarity of the high doped area 5 is of the same as of the surrounding or partially surrounding silicon substrate 1. That is to say, in the above example of an n-doped source-drain region the highly doped region 5 is as well n-doped.

The dopants are activated by a high temperature activation step which is typically used for dopant-activation (Spike-/Laser-/Flash-annealing) for some milliseconds up to seconds.

In a next step a contact modifying material 7 is deposited into and on the surface 6 of the silicon substrate 1 in the structured area 3. The embodiment is going to be outlined with sulphur as most preferred example for a contact modifying material 7, it should be understood that other contact modifying materials 7 listed later on can substitute for sulphur or used in addition to sulphur.

At the surface 6 of the silicon substrate 1 a very thin interface layer 8 of a few nanometers thickness 9 is formed comprising the preferably highly doped silicon substrate and the sulphur atoms 7 (FIG. 2). The concentration of the sulphur is exemplarily in the range of 10¹³-10¹⁵, preferably 0.5 10¹⁴-1.0 10¹⁴ sulphur atoms per square centimeter. A preferred implantation depth 9 of about 5-10 nanometers can be obtained by implanting the sulphur atoms with a kinetic energy of about 3-6 keV.

In a next step (FIG. 3) the silicon substrate 1 is silicided at its surface 6 in the structured area 3. A preferred metal for the silicide is titan or cobalt. A layer 10 of titan silicide or cobalt silicide 10 is formed or grown on the silicon substrate and on the layer 8 with the sulphur atoms.

The layer with the sulphur atoms 8 forms an interface layer between the highly doped silicon substrate 5 and the titan silicide or cobalt silicide layer 10. At the interface a Schottky barrier is formed. The sulphur atoms 7 in the interface layer 8 are reducing the contact resistivity. It was demonstrated that by use of sulphur the conductivity between the highly doped area 5 and the silicide layer 10 is increased by about 20-50%.

The formation of the contact is finished by depositing a metal, in particular titanium, titanium nitride or tungsten onto the silicide layer 10 (FIG. 4).

The deposition of the silicon atoms 7 and the growing of the silicide 10 can be effected in a single step. During the introduction of the metal, the sulphur atoms 7 can be inserted into a reaction chamber, as well.

A high temperature activation step for activating the sulphur atoms is not necessary and thus not effected.

The sulphur atoms can be implanted into the structured area 3 before the annealing step is effected.

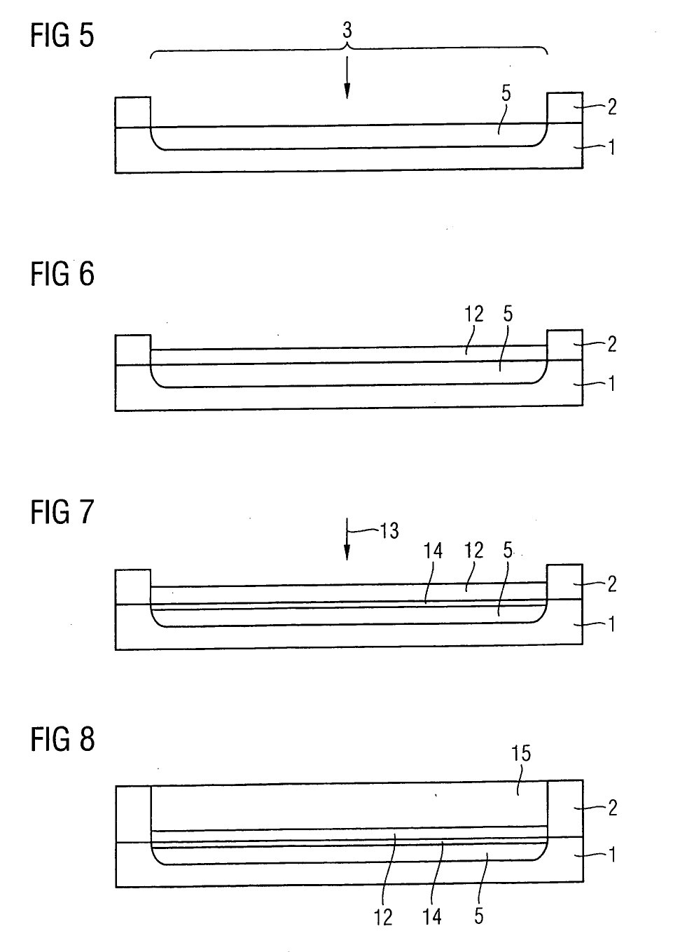

A second embodiment of the inventive method for forming a contact is illustrated along with FIGS. 5-8. At first a silicon substrate 1 is provided, which is structured via a mask 2 to define a structured area 3. The structured area 3 is prepared with a highly doped area 5, like in the first embodiment.

A silicide layer 12 is grown immediately onto the surface 6 of the silicon substrate 1 (FIG. 6). The silicide layer may consist of one the materials titan silicide and cobalt silicide or others listed herein above.

A contact modifying material 13 is implanted through the silicide layer 12, such that an interface layer 14 is formed between the silicide layer 12 and the silicon substrate or the highly doped area 5 of the silicon substrate 1. The contact modifying material is preferably sulphur. The implantation can be effected with a kinetic energy of the sulphur atoms of 3-6 keV.

The formation of the contact is finished by depositing a metal, preferably a metal corresponding to the metal forming the silicide layer 12 or by tungsten.

The implantation of the sulphur atoms or other contact modifying material through the silicide layer 12 can be applied after the doped material in the layer 5 is activated and crystal defects in the highly doped area 5 are annealed by a high temperature step. There is no need for an activation of the contact modifying material 13 in order to reduce the Schottky barrier height.

The Schottky barrier height is reduced, when the highly doped area 5 is doped with an n-doped material. In case the highly doped area 5 is doped with a p-doped material, the Schottky barrier height is not increased but basically remains constant.

This is surprising as a theoretic standard model would predict that the Fermi level of the silicide layer would be shifted by the content of sulphur. Such a shift would be beneficial for either n-doped areas or p-doped areas by reducing the Schottky barrier height. The Schottky barrier height of the respectively contrary doped area (either p-doped area or n-doped area in the above order), however, would be increased.

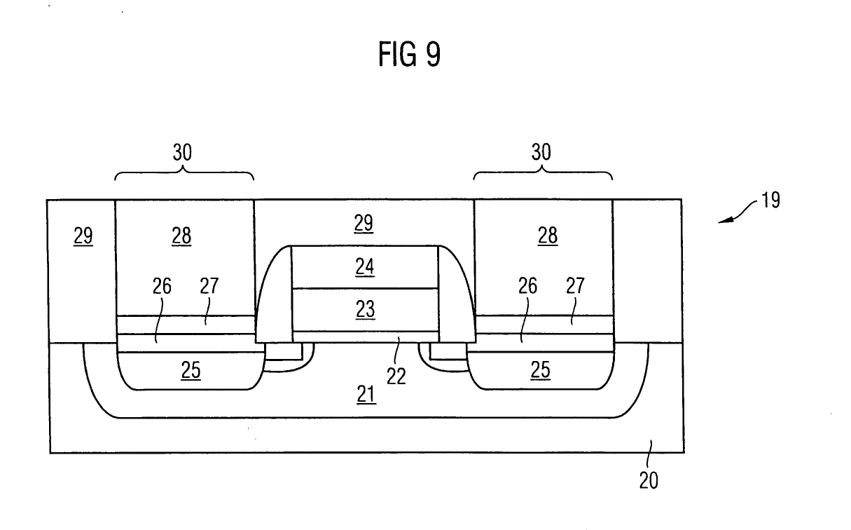

FIG. 9 illustrates a selection transistor used in the logic or support area of a DRAM memory device. These transistors 19 are used to address the bit- and the word-lines of the memory device. In the logic area both types of n-MOSFETS and p-MOSFETS are used. Exemplarily FIG. 9 shows an n-MOSFET. In the substrate 20 a p-doped well 21 is formed. A gate oxide 22 and a gate electrode 23, 24 are formed on the p-well 21. Source-drain regions 25 comprising an n-doped material are formed in the p-well 21.

An interface layer 26 comprising sulphur atoms and a metal silicide is formed on the source-drain regions 25. The metal silicide is preferably at least one of titan silicide and cobalt silicide. During the formation of the metal silicide sulphur atoms or other contact modifying material is introduced in the reaction chamber. Or the atoms are deposited via ion implantation into the metal silicide.

Onto the interface layer 26, a basically pure metal silicide layer 27 is applied. A metal plug 28 is formed on top of the silicide 27 to complete the contacts.

The interface layer 26, the silicide layer 27 and the metal plug 28 are preferably formed after a dielectric material 29 is deposited on the transistor structure 19 and openings are formed in the structured areas 30.

The formation of the interface layer and of the silicide layer can be effected by one of the methods illustrated with FIGS. 1-8.

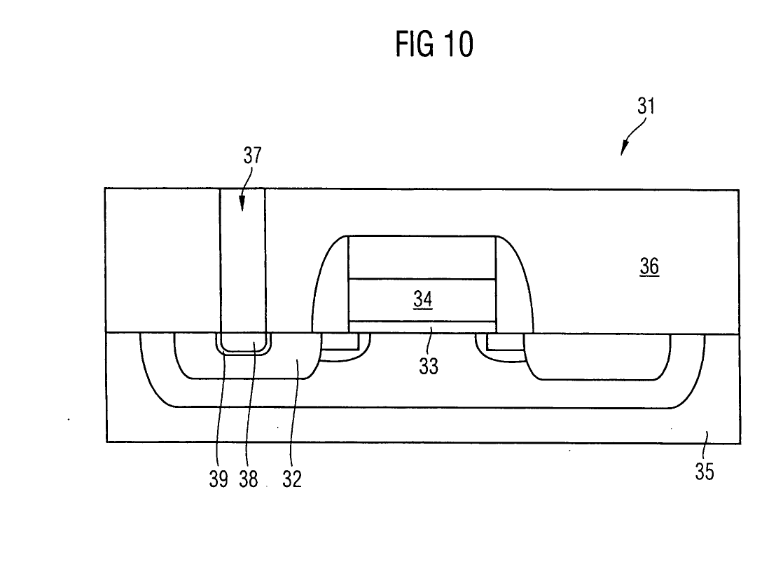

Along with FIG. 10 a second type of transistor 31 formed with one of the inventive methods illustrated with FIGS. 1-8 is shown in a partial cross section. In difference to the transistor 19 used for logic areas of DRAM-devices or a purely logic device, a contact to the source-drain regions 32 is differently formed. In first steps, the transistor 31 consisting of the source-drain regions 32 and the gate oxide 33 and the gate electrode 34 are formed in and onto the silicon substrate 35. In a next step, the transistor structure 31 is covered by a dielectric material 36. Openings 37 are formed in the area of the source-drain regions 32, which are to be connected, into the dielectric material 36.

A silicided area 38 is formed into the source-drain region 32. The metal and reactant gases are transported through the opening. The implantation of the sulphur atoms 39 takes place through the provided openings 37 in the dielectric material 36. The order of the steps: siliciding the source-drain region and implanting the sulphur atoms can be interchanged or effected at the same time. On top of the silicided area a metal plug is deposited for forming a CS-contact.

Although the present invention has been described with reference to a preferred embodiment, it is not limited thereto, but can be modified in various manners which are obvious for persons skilled in the art. Thus, it is intended that the present invention is only limited by the scope of the claims attached hereto.

Instead of sulphur as contact modifying material selenium, lanthanum, strontium, gadolinium, tellurium, rare earth metals can be used for interfaces of n-doped silicon and at least one of cobalt silicide and titan silicide. Aluminium, indium and gallium are suitable for interfaces of p-doped silicon. Germanium, silicon, xenon and argon can be used as contact modifying material, as well.

What is claimed is:

1. A method for manufacturing a semiconductor device, comprising the steps of:
(a) providing a silicon substrate comprising at least one structured area in which a dopant material is implanted;
(b) providing a contact modifying material on the surface of the at least one structured area; and
(c) forming a silicide layer on the modified surface of the at least one structured area, the silicide layer comprising at least one of titan silicide, titan nitride silicide, cobalt silicide, nickel silicide, ytterbium silicide, erbium silicide, platinum silicide, palladium silicide and rhenium silicide.

2. The method of claim 1, wherein the contact modifying material is introduced into a reaction chamber during the forming of the silicide layer.

3. A method for manufacturing a semiconductor device, comprising the steps of:
(a) providing a silicon substrate comprising at least one structured area in which a dopant material is implanted;
(b) forming a silicide layer on the surface of the at least one structured area, the silicide layer comprising at least one of titan silicide, titan nitride silicide, cobalt silicide, nickel silicide, ytterbium silicide, erbium silicide, platinum silicide, palladium silicide and rhenium silicide; and
(c) implanting a contact modifying material through the silicide layer to the surface of the at least one structured area.

4. The method according to claim 1, wherein the contact modifying material comprises sulphur.

5. The method according to claim 3, wherein the contact modifying material comprises sulphur.

6. The method according to claim 1, wherein the contact modifying materials is at least one of selenium, lanthanum, strontium, gadolinium, tellurium, rare earth metals for n-doped structured areas; at least one of aluminium, indium and gallium for p-doped structured areas; or at least one of germanium, silicon, xenon and argon.

7. The method according to claim 3, wherein the contact modifying materials is at least one of selenium, lanthanum, strontium, gadolinium, tellurium, rare earth metals for n-doped structured areas; at least one of aluminium, indium and gallium for p-doped structured areas; or at least one of germanium, silicon, xenon and argon.

8. The method according to claim 1, wherein the silicon substrate is provided with prefabricated semiconductor devices which are contacted via the structured areas; an isolation layer is provided over the silicon substrate for covering the prefabricated semiconductor devices; openings are formed into the isolation layer; the contact modifying material is provided through the opening; and the silicide layer is formed in the opening.

9. The method according to claim 3, wherein the silicon substrate is provided with prefabricated semiconductor devices which are contacted via the structured areas; an isolation layer is provided over the silicon substrate for covering the prefabricated semiconductor devices; openings are formed into the isolation layer; the contact modifying material is provided through the opening; and the silicide layer is formed in the opening.

10. A method for manufacturing a semiconductor device, comprising the steps in the following order:
(a) providing a silicon substrate comprising at least one structured area in which a dopant material in a concentration of at least of 5*10¹⁸ atoms per cm³ is implanted;
(b) implanting sulphur into the surface of the at least one structured area in a surface concentration of 10¹³-10¹⁵ atoms per square centimeter;
(c) activating the dopant material via a high temperature annealing step;
(d) forming a silicide layer on the modified surface of the at least one structured area, the silicide layer comprising at least one of titan silicide, titan nitride silicide, cobalt silicide, nickel silicide, ytterbium silicide, erbium silicide, platinum silicide, palladium silicide and rhenium silicide.

11. A method for manufacturing a semiconductor device, comprising the steps in the following order:
(a) providing a silicon substrate comprising at least one structured area in which a dopant material in a concentration of at least of 5*10¹⁸ atoms per cm³ is implanted;
(b) activating the dopant material via a high temperature annealing step;
(c) implanting sulphur into the surface of the at least one structured area in a surface concentration of 10¹³-10¹⁵ atoms per square centimeter;
(d) forming a silicide layer on the modified surface of the at least one structured area, the silicide layer comprising at least one of titan silicide, titan nitride silicide, cobalt silicide, nickel silicide, ytterbium silicide, erbium silicide, platinum silicide, palladium silicide and rhenium silicide.

12. A semiconductor transistor, comprising:
a source/drain region,
a contact comprising a lower portion made of at least one of titan silicide, titan nitride silicide and cobalt silicide;
a conductive layer comprising sulphur an upper side of the layer being adjacent to the metal silicide and a lower of the layer being adjacent to the source/drain region.

13. The semiconductor transistor according to claim 12, wherein the lower portion of the contact extends into the source/drain region.

14. The semiconductor transistor according to claim 12, wherein the lower portion of the contact is planar and covers a top surface of the source/drain region.

15. A semiconductor memory device comprising a transistor according to claim 12 in at least one of a support area and a memory cell area.

16. A semiconductor transistor comprising:
a source/drain region,
a contact comprising a lower portion made of at least one of titan silicide, titan nitride silicide and cobalt silicide;
a conductive layer comprising sulphur at an upper side of the layer being adjacent to the metal silicide of the contact and a lower side of the layer being adjacent to the source/drain region.
